(19) United States
(12) Patent Application Publication
(10) Pub. No.: US 2014/0311652 A1
(43) Pub. Date: Oct. 23, 2014

(54) Method And Apparatus For Mounting Electronic Or Optical Components On A Substrate

(71) Applicant: Besi Switzerland AG, Cham (CH)

(72) Inventors: Hannes Kostner, Absam (AT); Andreas Mayr, Wiesing (AT); Harald Meixner, Buch (AT); Hugo Pristauz, St. Johann i. Tirol (AT)

(73) Assignee: Besi Switzerland AG, Cham (CH)

(21) Appl. No.: 14/256,830

(22) Filed: Apr. 18, 2014

(30) Foreign Application Priority Data
Apr. 19, 2013 (CH) 800/13

(51) Int. Cl. H01L 21/68

(52) U.S. Cl. CPC H01L 21/68
USPC 156/64; 156/60; 156/538; 156/378

(57) ABSTRACT

A method for mounting components on a substrate includes receiving a component with a suction member which is mounted on a bonding head, displacing the bonding head relative to the substrate by means of a first movement axis and a second movement axis in order to position the component in a target position above the substrate, lowering the suction member by means of a third movement axis until the component touches the substrate, producing a predetermined bonding force with which the suction member presses the component against the substrate, and displacing at least one of the bonding head and the substrate by means of at least one of the first movement axis by a corrective value W₁ and the second movement axis by a corrective value W₂ in order to correct an inclined position of the suction member produced during the build-up of the bonding force.

### PRIORITY CLAIM

Applicant hereby claims foreign priority under 35 U.S.0 § 119 from Swiss Application No. 800/13 filed Apr. 19, 2013, the disclosure of which is herein incorporated by reference.

### FIELD OF THE INVENTION

The invention relates to a method for mounting electronic or optical components, in particular semiconductor chips (also known as dies) on a substrate. The term “component” as used in the claims refers to such electronic and/or optical components.

### BACKGROUND OF THE INVENTION

The mounting of the components occurs in the semiconductor industry by means of automatic semiconductor mounting machines which are known in the field as die bonders or pick-and-place machines. The components are often semiconductor chips which are placed and bonded on various types of substrates. The components are taken up by a chip gripper, especially a suction member, are moved to the place of deposit over the substrate and are placed at a precisely defined position on the substrate. The chip gripper or the suction member is usually rotatably mounted about its longitudinal axis on a bonding head. The bonding head is fixed to a pick-and-place system, which enables the required movements in the three spatial directions X, Y and Z. The Z direction corresponds in this case and with reference to the text below to the vertical direction, whereas the XY plane forms the horizontal plane.

In addition to the highly precise positioning of the components in the XY plane, it is highly important that the components are placed in a plane-parallel manner and free of shearing forces on the substrate. A tilted placement of the components can lead to undesirable properties such as reduced holding force, inadequate or missing electrical contacts, irregular transmission of heat between components and substrate, or damage to the components. Shearing forces can lead to slippage of the semiconductor chip.

It is a serious problem during the mounting process that when the component is pressed against the substrate reaction forces are produced as a result of the pressing forces which are generated in this process and are far from being inconsiderable, and which can lead to a deformation of the pick-and-place system and/or the base on which the substrate is situated. Such a deformation can lead to a tilting of the bonding head relative to the surface of the substrate and therefore to an axial error (tilt), leading to a respective tilted position of the component relative to the surface of the substrate. Such a deformation can further produce shearing forces and can subsequently lead to slippage of the semiconductor chip. FIGS. 1 and 2 illustrate the occurrence of an axial error on the basis of a simple schematic illustration of a pick-and-place system 1, to which a bonding head 2 is fixed which comprises a suction member 3 for sucking up a semiconductor chip 4, and a substrate base 5 on which the substrate 6 rests and is tightly held. The force exerted by the suction member 3 on the substrate 5 is usually known as the bonding force. FIG. 1 shows the aforementioned objects in the unloaded state, and FIG. 2 shows the aforementioned objects under the influence of a bonding force F, which produces an axial error. The axial error is designated as the angle θ.

It is known for avoiding this undesirable axial error to arrange the pick-and-place system as stiffly as possible. Despite optimized technology in light construction, this inevitably leads to a relatively large mass. As a result of the massive construction, the throughput of the semiconductor die bonder decreases considerably in combination with the given drive power. Furthermore, even in the case of a highly massive configuration of the pick-and-place system and the substrate base it is not possible to entirely prevent that the suction member will slightly spread during pressing on the substrate.

In the following, the terms “tilt” and “inclined position” and terms derived therefrom are used synonymously.

### SUMMARY OF THE INVENTION

The invention is therefore based on the object of recognising and/or eliminating a potential axial error of the suction member and further problems which are caused by the deformation of the pick-and-place system and/or the substrate base caused during the build-up of the bonding force, without having to arrange the pick-and-place system in an especially stiff way.

The invention is based on the finding that the deformation of the system caused by the bonding force substantially entails two undesirable effects, of which the one is the main effect and the other is the secondary effect, depending on the configuration of the system. The first effect is a tilting and the positional offset of the bonding head resulting therefrom, which leads to an inclined position (tilt) of the suction member. An inclined position of the suction member is produced when the deformation of the system leads to a tilting of the bonding head about a pivot point which differs from the pivot point about which the suction member can tilt relative to the bonding head. The second effect is caused by restoring forces acting on the suction member, which can lead to slippage of the component on the substrate. Such restoring forces are produced in the bearing of the bonding head and act on the suction member when the deformation of the system leads to the consequence that the bonding head is tilted relative to the suction member.

The compensation of the first effect occurs according to a first aspect of the invention by a first method which comprises the following steps:
A) Receiving the component with a suction member which is mounted on a bonding head, wherein the bonding head is displaceable relative to the substrate by means of a first movement axis and a second movement axis which span a plane, and wherein the bonding head and/or the suction member is displaceable by means of a third movement axis which extends perpendicularly to the aforementioned plane;
B) displacing the bonding head by means of the first movement axis and the second movement axis in order to position the component in a target position above the substrate;
C) lowering the suction member by means of the third movement axis until the component touches the substrate, and producing a predetermined bonding force with which the suction member presses the component against the substrate, and
D) displacing the bonding head and/or the substrate by means of the first movement axis by a corrective value W₁ and/or by means of the second movement axis about a corrective value W₂ in order to correct an inclined position of the suction member produced during the build-up of the bonding force, wherein the corrective values W₁ and W₂ are either
   determined by means of stored calibration data, or
   determined by measured values supplied by a sensor and stored calibration data, or
   are produced by means of a closed-loop control unit which is based on measurement signals supplied by a sensor.

In accordance with a second aspect of the invention, a second method comprises the steps A to C of the first method, and the steps
D) measuring a potentially inclined position of the suction member or a physical quantity depending on a potentially inclined position of the suction member by means of a sensor;
E) logging the measured value supplied by the sensor, and optionally
F) terminating the process when a measured value supplied by the sensor leads to the result that the inclined position of the suction member exceeds a predetermined limit value.

A physical quantity which is dependent on the inclined position of the suction member is a torque for example. A two-axis or multi-axis torque sensor is suitable in this case for example as a sensor, which measures at least the torques produced by the inclined position of the suction member in the XZ plane and in the YZ plane. As the sensor it is also possible to use any other sensor which is capable of measuring the inclined position of the suction member. The sensor can be an optical sensor for example which detects the altitude of three points of the suction member, which are arranged at a distance from each other and therefore define a plane. The position of the plane in space depends on the position of the suction member.

The compensation of the second effect occurs according to a third aspect by a third method, which comprises the steps A to C of the first method, and the following steps:
D) measuring at least one shearing force by means of a sensor, which shearing force exists as a result of a force acting from the bonding head on the suction member, and
E) actuating at least one actuator with which a force can be produced acting in a predetermined direction on the bonding head, for compensating or reducing the measured at least one shearing force.

A semiconductor mounting apparatus which is suitable for this purpose preferably comprises two actuators. In this case, the sensor is preferably configured in such a way that it measures the shearing force produced in the XY plane in the X direction and/or the shearing force produced in the Y direction. The directions of force of the actuators lie in the XY plane. Preferably, the direction of force of the first actuator is the X direction and the direction of force of the second actuator is the Y direction. The steps D and E are then:
D) measuring a first and a second shearing force by a sensor, and
E) actuating a first actuator and/or a second actuator, wherein a force acting in a first direction on the bonding head can be produced by the first actuator and a force acting in a second direction on the bonding head can be produced by the second actuator, for compensating or reducing the measured shearing force/shearing forces.

However, a semiconductor mounting apparatus which is suitable for this purpose can also comprise three actuators, which are angularly arranged offset from each other by 120° each and which are used for compensating or reducing the measured shearing force/shearing forces.

In accordance with a fourth aspect of the invention, a fourth method comprises the steps A to D of the third method, and the steps
E) logging of the measured values supplied by the sensor, and optionally
F) terminating the mounting process when a measured value supplied by the sensor leads to the consequence that the measured at least one shearing force exceeds a predetermined limit value.

Both the first effect and also the second effect or both effects can be compensated by means of a semiconductor mounting apparatus which comprises the aforementioned three movement axes and the aforementioned two actuators. In this case, the sensor is at least a four-axis force-torque sensor, which measures on the one hand the torques produced by the inclined position of the suction member in the XZ plane and in the YZ plane and on the other hand the shearing forces produced in the XY plane in the X direction and the Y direction. It is understood that a six-axis force-torquce sensor can also be used, since six-axis force-torquce sensors can be obtained more easily than four-axis force-torquce sensors.

The term sensor shall be understood in a wide sense, in that the sensor can also be a sensor system with several individual sensors and/or can supply more than one output signal.

### BRIEF DESCRIPTION OF THE DRAWING FIGURES

The accompanying drawings, which are incorporated into and constitute a part of this specification, illustrate one or more embodiments of the present invention and, together with the detailed description, serve to explain the principles and implementations of the invention. The figures are not to scale. In the drawings:

FIG. 1 schematically shows parts of a semiconductor mounting apparatus in the unloaded state;

FIG. 2 shows the aforementioned parts in the loaded state;

FIG. 3 schematically shows a semiconductor mounting apparatus insofar as it is necessary for the understanding of the method in accordance with the invention;

FIGS. 4-6 show three snapshots in a highly exaggerated manner during the method in accordance with the invention, and

FIG. 7 shows a further semiconductor mounting apparatus.

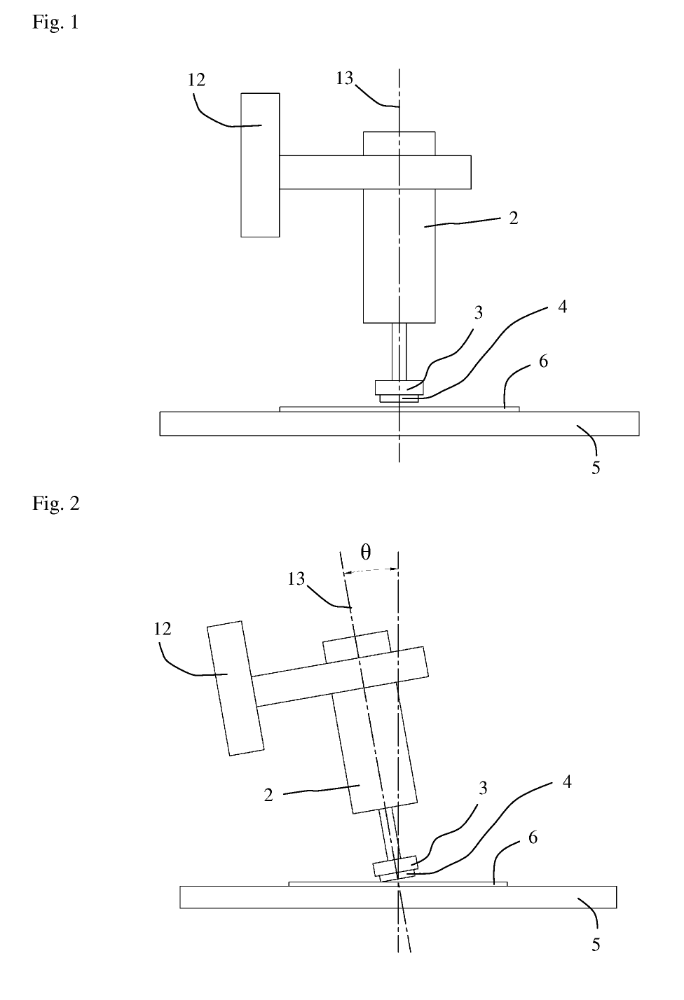

### DETAILED DESCRIPTION OF THE INVENTION

The method in accordance with the invention for mounting electronic or optical components, especially semiconductor chips, on a substrate is performed by means of an automatic semiconductor mounting apparatus, i.e. especially a die bonder or a pick-and-place machine, which comprises a bonding head 2 with a suction member 3. FIG. 3 shows an embodiment of a semiconductor mounting apparatus as required for understanding the method in accordance with the invention. The semiconductor mounting apparatus comprises a first movement axis and a second movement axis, which are used to displace the bonding head 2 relative to the substrate 6 in a predetermined plane. The XY plane spanned by the two movement axes is the horizontal plane in this example. The bonding head 2 and/or suction member 3 are displaceable by means of a third movement axis which extends perpendicularly to the XY plane in the Z direction. The three movement axes are axes driven electrically and/or pneumatically, and are part of a pick-and-place system and/or a transport apparatus for the transport of the substrates 6 and enable the relative displacement of the suction member 3 with respect to the substrate 6. Such a movement axis comprises a guide, a movable part, e.g. a carriage movable in the guide, and an associated drive. The bearing of the carriage can occur in different ways, e.g. by means of an air bearing or a ball bearing. There is therefore a certain amount of elasticity between the guides and the movably mounted carriages, which elasticity is typically slightly larger in an air bearing than in a ball bearing.

The first movement axis comprises first guides 7, on which a first carriage 8 is displaceable in the X direction. The second movement axis comprises second guides 9, on which a second carriage 10 is displaceable in the Y direction. The second guides 9 are attached to the first carriage 8. The third movement axis comprises third guides 11, which are attached to the second carriage 10, and a third carriage 12 to which the bonding head 2 is fastened. In this embodiment, the three movement axes are part of an XYZ pick-and-place system. Each movement axis further comprises a drive (not shown) in order to displace the associated carriage along the associated guide.

A fourth movement axis is advantageously provided, which enables the movement of the suction member 3 relative to the bonding head 2, wherein the direction of the fourth movement axis is equal to the direction of the third movement axis, i.e. the Z direction in this case. The fourth movement axis thus enables a movement of the suction member 3 along its longitudinal axis 13. The fourth movement axis can be provided without drive, so that it (only) allows passive movements. The suction member 3 is usually rotatably mounted about its longitudinal axis 13 on the bonding head 2. The bearing of the suction member 3 on the bonding head 2 preferably occurs by means of an air bearing. The bonding force is preferably produced pneumatically or electromechanically, wherein the components necessary for this purpose are preferably arranged between the bonding head 2 and the suction member 3.

When the bonding force is built up during the mounting of the semiconductor chip 4, a torque is produced as a result of the unilateral asymmetric bearing of the bonding head 2 on the third carriage 12, which torque changes the direction of the longitudinal axis of the suction member 3 due to the limited stiffness or the elasticity, respectively, of the movement axes and their bearings: the longitudinal axis of the suction member 3 no longer extends parallel to the Z direction but diagonally in relation to the Z direction. The tilted position can be characerized by two angles θ₁ and θ₂, namely by the angle of inclination θ₁ of the longitudinal axis of the suction member 3 in the XZ plane and the angle of inclination θ₂ in the YZ-plane. This also leads to an inclined position of the semiconductor chip 4 with the consequence that the bottom side of the semiconductor chip 4 and the substrate 6 are no longer aligned in a plane-parallel manner with respect to each other. The emerging torque or the emerging direction of the longitudinal axis of the suction member 3 depends on the bonding force on the one hand and also on the location on the other hand where the first carriage 8 is situated with respect to the first guide 7, the second carriage 10 with respect to the second guide 9 and the third carriage 12 with the bonding head 2 with respect to the third guide 11.

In order to correct this inclined position, the bonding head 2 is displaced by means of the first and/or second movement axis to such an extent that the longitudinal axis of the suction member 3 extends in parallel to the Z direction again. The static friction between the semiconductor chip 4 and the substrate 6 ensures that the semiconductor chip 4 will not slip on the substrate 6. It is thus sufficient to perform the corrective movements of the first and second movement axis when the build-up of the bonding force is completed.

The method in accordance with the invention for the mounting of a semiconductor chip or a component therefore comprises in such a semiconductor mounting apparatus the following steps for the correction of the first effect, i.e. the correction of the inclined position of the suction member 3:
receiving the component with the suction member 3;
displacing the bonding head 2 by means of the first movement axis and the second movement axis in order to position the component in a target position above the substrate 6;
lowering the suction member 3 by means of the third movement axis until the component touches the substrate 6, and producing the predetermined bonding force with which the suction member 3 must press the component against substrate 6, and
displacing the bonding head 2 by means of the first movement axis about a corrective value W₁ and/or by means of the second movement axis about a corrective value W₂ in order to correct an inclined position of the longitudinal axis of the suction member 3 occurring during the build-up of the bonding force.

The generation of the bonding force and the displacement of the bonding head 2 can occur simultaneously in order to prevent the occurrence of a torque and therefore an inclined position of the longitudinal axis of the suction member 3 right from the start.

The expression of “displacement of the bonding head 2” by means of a movement axis means that either the bonding head 2 or the substrate 6 is displaced according to the construction chosen for the movement axis, since the relative displacement is relevant.

The corrective values W₁ and W₂ are either
1) determined by means of stored calibration data or
2) determined from the measured values supplied by a sensor 14 and stored calibration data, or
3) produced in a control circuit by means of a measurement signal supplied by a sensor 14.

In the variant 1, the corrective values W₁ and W₂ are determined on the basis of position data, i.e. on the basis of the target positions of the first movement axis and the second movement axis assumed by the bonding head 2 above the substrate position and stored calibration data. In the variant 2, the corrective values W₁ and W₂ are determined by means of the measurement signals supplied by the sensor 14 and stored calibration data. As indicated by the name, the calibration data are determined previously in a calibration process by means of the sensor 14 which is positioned at the location of the substrate 6 on the substrate base 5 or is arranged on or installed in the suction member 3 or bonding head 2. In the embodiment as shown in FIG. 3, the sensor 14 is built into the suction member 3. The calibration data can be stored for example in form of a lookup table or in form of a function or in any other suitable form.

The term sensor is used in a way which also includes the relevant electronics. The sensor 14 supplies at least two measuring signals. The measuring signals contain for example the information on the angle of inclination θ₁ and the angle of inclination θ₂ of the longitudinal axis of the suction member 3 and/or the information on the torque in the XZ plane and the torque in the YZ plane, which is exerted by the component held by the suction member 3 on the substrate 6. The inclined position of the suction member 3 is so small that it is invisible to the eye. For this reason the sensor 14 is preferably a sensor which can measure the torque exerted by the suction member 3 on the substrate base 5 along the first movement axis and the torque exerted along the second movement axis. Such a sensor is a two-axis torque sensor for example. Six-axis force-torque sensors, which are available on the market, are also suitable. An optical sensor such as an optical triangulation measuring system or an inductive sensor or any other suitable sensor can be used alternatively.

A preferred manner to determine the corrective values W₁ and W₂ is explained below in more detail for the three mentioned variants.

### Variant 1=Use of Position Data and Stored Calibration Data for Determining the Corrective Values W₁ and W₂

The bonding head 2 is moved to the respective X, Y position above the substrate 6 during the mounting of a semiconductor chip 4. The corrective values W₁ and W₂ assigned to this position are then determined by means of the calibration data, when stored in a lookup table, if necessary by means of interpolation. The calibration data therefore represents the relationship between the X, Y position of the bonding head 2 (and optionally further parameters such as the bonding force) and the corrective values W₁ and W₂.

Variant 2=Use of a Sensor and Stored Data for Determining the Corrective Values W₁ and W₂

This variant is similar to the variant 1, but with the difference that the sensor 14 is permanently installed, either in the substrate base 5 or in the suction member 3 or in the bonding head 2. The bonding head 2 is moved to the respective X, Y position above the substrate 6 during the mounting of a semiconductor chip 4, and the bonding head 2 is lowered until the bonding force has been built up. The corrective values W₁ and W₂ to be assigned then to the measured values which are supplied by the sensor 14 are determined by means of calibration data, when stored in a lookup table, if necessary by means of interpolation. The calibration data therefore represent the relationship between the measurement signals of the sensor 14 and the corrective values W₁ and W₂.

Variant 3=Displacing the Bonding Head Along the First and/or Second Movement Axis by Controlling the Corrective Values W₁ and W₂ on the Basis of the Measurement Signals of a Sensor

In this variant, the sensor 14 is permanently installed in the substrate base 5 or in the suction member 3 or in the bonding head 2. The measurement signals of the sensor 14 are used to control the X position of the bonding head 2 assumed by the first movement axis and the Y position of the bonding head 2 assumed by the second movement axis in such a way that the torques disappear. The closed-loop control produces in this manner the correction of the X position and the Y position of the bonding head 2 by the required corrective values W₁ and W₂.

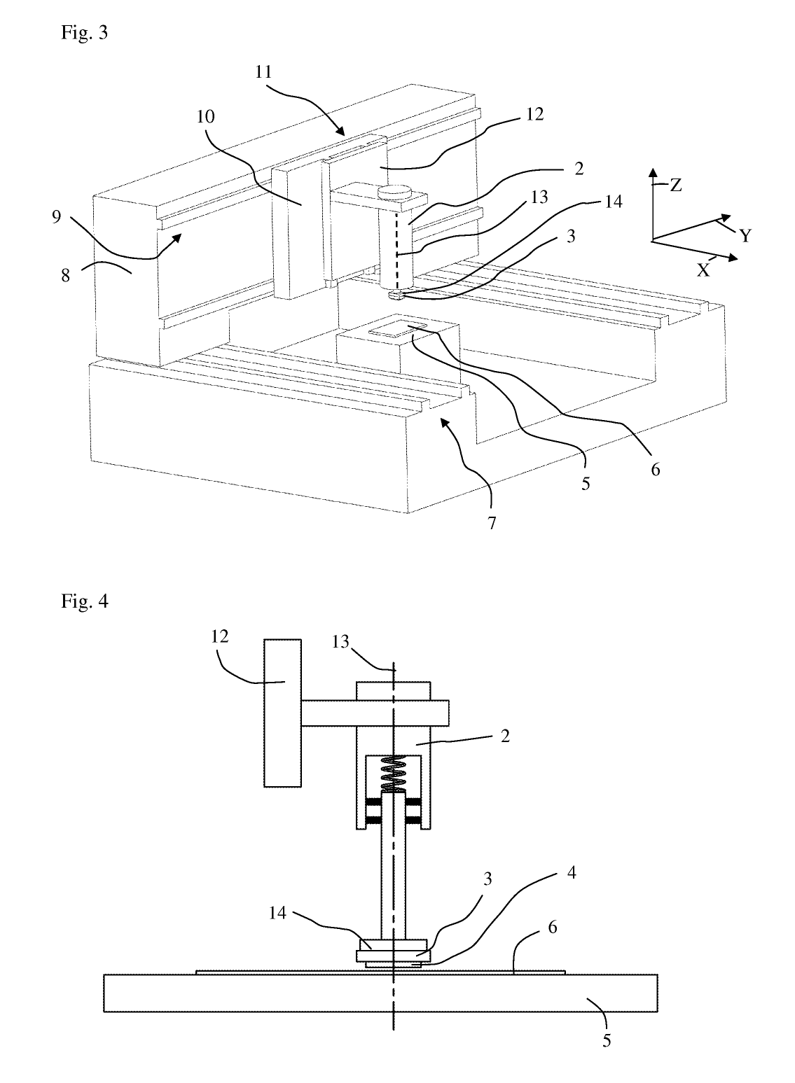

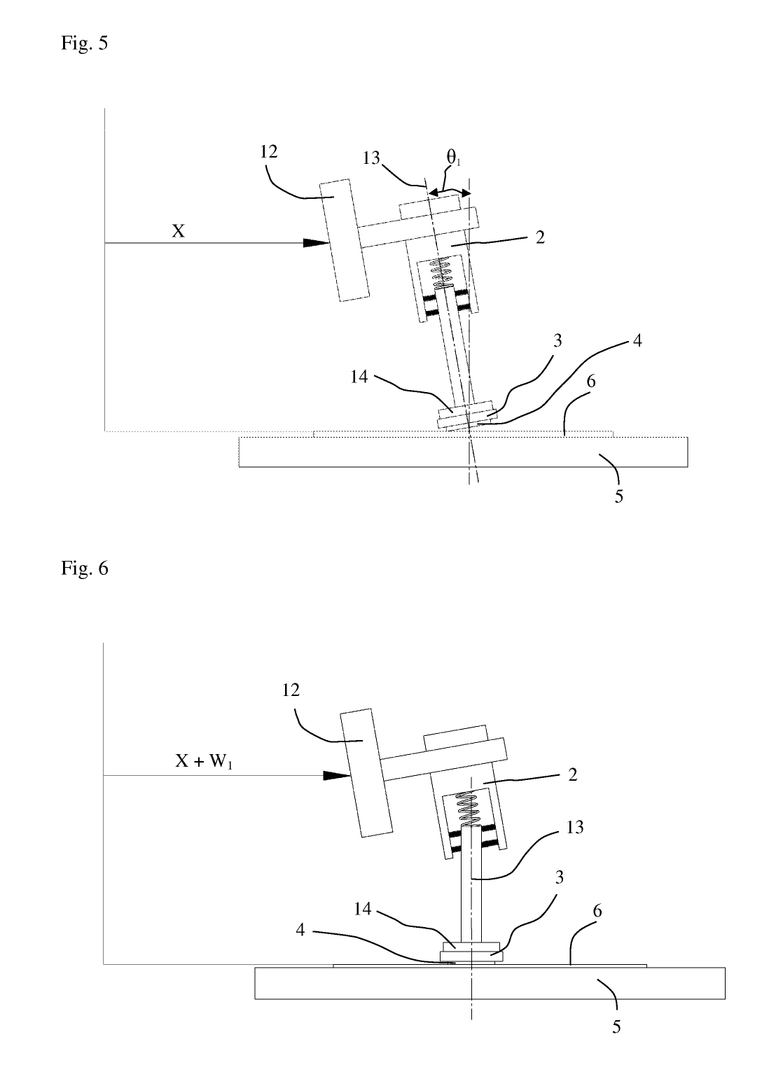

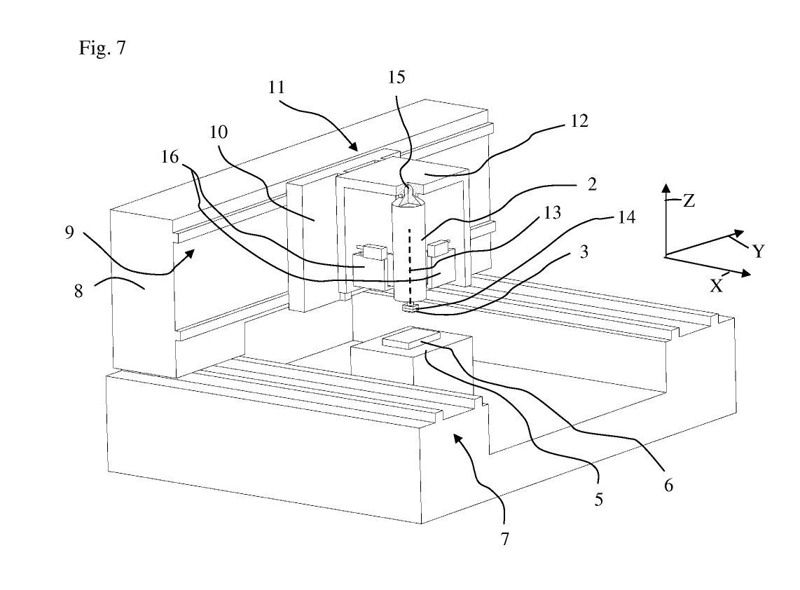

FIGS. 4 to 6 schematically show three snapshots of the pick-and-place system during the method in accordance with the invention. The deformation of the system produced by the bonding force F is shown in a strongly exaggerated manner. It is not visible to the naked eye. FIG. 4 shows the state at the point in time at which the first movement axis is situated at the target position X and the bonding force F, with which the suction member 3 presses the semiconductor chip 4 against substrate 6, has not yet been built up. The movement axes extend in their targets directions. FIG. 5 shows the state at the point in time at which the bonding force has been built up. The movement axes no longer extend in their target directions due to the applied bonding force F and the elasticity of the system, which leads to an inclination of the longitudinal axis of the suction member 3 in the XZ plane about the angle θ₁ and in the YZ plane about the angle θ₂ (not shown). This is illustrated in FIG. 5 in an exaggerated manner by the inclined position of the third carriage 12 of the pick-and-place system and the suction member 3. FIG. 6 shows the state of the pick-and-place system at the point in time at which the corrective movement about the distance W₁ has been completed. The first movement axis is now situated at the position X+W₁. The longitudinal axis of the suction member 3 now extends perpendicularly to the surface of the substrate 6 again. The bonding force F still acts, which is why the directions of the movement axes of the pick-and-place system still deviate from their target directions. In the example shown in FIGS. 4 to 6, it is due to the elasticity of the bearing between the suction member 3 and the bonding head 2 that the longitudinal axis 13 of the suction member 3 is capable of rotating about the angle θ₁ bzw. θ₂ during the corrective movement, so that the longitudinal axis 13 is aligned perpendicularly to the substrate 6 at the end of the corrective movement. The orientation of the longitudinal axis 13 of the suction member 3 perpendicularly to the substrate 6 which is achieved by the corrective movement can also be achieved in other ways, e.g. because other parts of the pick-and-place system 1 have the required elasticity or because the bonding head 2 is mounted by means of a solid joint and/or cardanic bearing or a ball-and-socket joint on the third carriage 12 of the pick-and-place system 1. An example of a bearing of the bonding head 2 by means of a ball-and-socket joint 15 is shown in FIG. 7.

Generating the bonding force and displacing the bonding head 2 can occur simultaneously in order to prevent the origination of a torque and therefore an inclined position of the longitudinal axis of the suction member 3 right from the start.

As is shown in FIG. 6, the suction member 3 is aligned perpendicularly after the corrective movement, which does not mandatorily also apply to the bonding head 2. The bonding head 2 therefore exerts a force/forces on the suction member 3, which then leads to the aforementioned shearing forces between the semiconductor chip 4 and the substrate 6.

In order to at least detect the second effect, i.e. the shearing forces exerted by the suction member 3 or the semiconductor chip 4, in the semiconductor mounting apparatus as shown in FIG. 3, the sensor 14 is a four-axis or six-axis force-torque sensor, which measures the torques acting by the inclined position of the suction member 3 in the XZ plane and in the YZ plane on the one hand and the shearing forces acting in the XY plane in the X direction and the Y direction on the other hand. The semiconductor mounting apparatus is then preferably configured to log the values measured by the sensor and/or to stop the mounting process when at least one of the measured shearing forces exceeds a predetermined limit value.

In order to compensate the second effect, the semiconductor mounting apparatus additionally comprises at least one actuator (preferably two or three thereof) between the third carriage 12 and the bonding head 2. In the case of an arrangement with two actuators 16, the first one can produce a force acting in the X direction on the bonding head 2 for example and the second a force acting in the Y direction on the bonding head 2 for example. An example of such a semiconductor mounting apparatus is shown in FIG. 7. Both an undesirable inclined position of the suction member 3 and also undesirable shearing forces can be compensated in this semiconductor mounting apparatus. In the case of an arrangement with three actuators 16, they are arranged for example in an offset manner at a respective angle of 120° with respect to each other.

In this semiconductor mounting apparatus, the actuators 16 can also be used as a sensor in order to detect and measure a potentially inclined position of the suction member 3 which occurs during the impact of the semiconductor chip 4 on the substrate 6, in that they supply a feedback signal which in a position mode of the actuators 16 contains information on a change in the position caused by the inclined position of the suction member 3 or in a force mode of the actuators 16 contains information on a change in the force caused by the inclined position of the suction member 3.

The level of deformation of the system produced by the bonding force on the inclined position of the suction member 3 and the magnitude of the occurring shearing forces depend on the specific construction of the semiconductor mounting apparatus. Whereas generally the inclined position can assume any desired direction and the shearing force can also assume any desired direction, it may also occur in individual cases that the inclined position occurs in a predetermined plane and/or the shearing force in a predetermined direction. It is sufficient in this case that the sensor is only capable of measuring one torque or one shearing force and the corrections occur accordingly. Consequently, only one actuator would be necessary.

While embodiments and applications of this invention have been shown and described, it would be apparent to those skilled in the art having the benefit of this disclosure that many more modifications than mentioned above are possible without departing from the inventive concepts herein. The invention, therefore, is not to be restricted except in the spirit of the appended claims and their equivalents.

What is claimed is:

1. A method for mounting components on a substrate, comprising
receiving a component with a suction member which is mounted on a bonding head, wherein the bonding head is displaceable relative to the substrate by means of a first movement axis and a second movement axis which span a plane, and wherein the suction member is displaceable by means of a third movement axis which extends perpendicularly to the aforementioned plane;
displacing the bonding head by means of the first movement axis and the second movement axis in order to position the component in a target position above the substrate;
lowering the suction member by means of the third movement axis until the component touches the substrate, and producing a predetermined bonding force with which the suction member presses the component against the substrate; and
displacing at least one of the bonding head and the substrate along at least one of a first direction by a corrective value W₁ and a second direction by a corrective value W₂ in order to correct an inclined position of the suction member produced during the build-up of the bonding force; wherein the corrective values W₁ and W₂ are determined by one of:
stored calibration data,
measured values supplied by a sensor and stored calibration data, and
a closed-loop control based on measurement signals supplied by a sensor.

2. A method for mounting components on a substrate, comprising
receiving a component with a suction member which is mounted on a bonding head, wherein the bonding head is displaceable relative to the substrate by means of a first movement axis and a second movement axis which span a plane, and wherein the suction member is displaceable by means of a third movement axis which extends perpendicularly to the aforementioned plane;
displacing the bonding head by means of the first movement axis and the second movement axis in order to position the component in a target position above the substrate;
lowering the suction member by means of the third movement axis until the component touches the substrate, and producing a predetermined bonding force with which the suction member presses the component against the substrate; and
measuring at least one shearing force which exists as a result of a force acting from the bonding head on the suction member; and
actuating at least one actuator, with which a force can be produced acting in a predetermined direction on the bonding head, for counteracting the measured at least one shearing force.

3. A method for mounting components on a substrate, comprising
receiving a component with a suction member which is mounted on a bonding head, wherein the bonding head is displaceable relative to the substrate by means of a first movement axis and a second movement axis which span a plane, and wherein the suction member is displaceable by means of a third movement axis which extends perpendicularly to the aforementioned plane;
displacing the bonding head by means of the first movement axis and the second movement axis in order to position the component in a target position above the substrate;
lowering the suction member by means of the third movement axis until the component touches the substrate, and producing a predetermined bonding force with which the suction member presses the component against the substrate; and
using a sensor to measure at least one of:
a potentially inclined position of the suction member,
a physical quantity dependent on an inclined position of the suction member, and
at least one shearing force which exists as a result of a force acting by the bonding head on the suction member.

4. The method of claim 3, further comprising
stopping the mounting when at least one of:
a measured torque exceeds a limit value, and
a measured shearing force exceeds a limit value.

5. The method of claim 4, wherein the sensor is a multi-axis force-torque sensor.

6. An apparatus for mounting components on a substrate, the apparatus configured to perform the following steps:
receiving a component with a suction member which is mounted on a bonding head, wherein the bonding head is displaceable relative to the substrate by means of a first movement axis and a second movement axis which span a plane, and wherein the suction member is displaceable by means of a third movement axis which extends perpendicularly to the aforementioned plane;
displacing the bonding head by means of the first movement axis and the second movement axis in order to position the component in a target position above the substrate;
lowering the suction member by means of the third movement axis until the component touches the substrate, and producing a predetermined bonding force with which the suction member presses the component against the substrate; and
displacing at least one of the bonding head and the substrate along at least one of a first direction by a corrective value W₁ and a second direction by a corrective value W₂ in order to correct an inclined position of the suction member produced during the build-up of the bonding force; wherein the corrective values W₁ and W₂ are determined by one of:
stored calibration data,
measured values supplied by a sensor and stored calibration data, and
a closed-loop control based on measurement signals supplied by a sensor.

7. An apparatus for mounting components on a substrate, the apparatus configured to perform the following steps:
receiving a component with a suction member which is mounted on a bonding head, wherein the bonding head is displaceable relative to the substrate by means of a first movement axis and a second movement axis which span a plane, and wherein the suction member is displaceable by means of a third movement axis which extends perpendicularly to the aforementioned plane;
displacing the bonding head by means of the first movement axis and the second movement axis in order to position the component in a target position above the substrate;
lowering the suction member by means of the third movement axis until the component touches the substrate, and producing a predetermined bonding force with which the suction member presses the component against the substrate; and
measuring at least one shearing force which exists as a result of a force acting from the bonding head on the suction member; and
actuating at least one actuator, with which a force can be produced acting in a predetermined direction on the bonding head, for counteracting the measured at least one shearing force.

8. An apparatus for mounting components on a substrate, the apparatus configured to perform the following steps:
receiving a component with a suction member which is mounted on a bonding head, wherein the bonding head is displaceable relative to the substrate by means of a first movement axis and a second movement axis which span a plane, and wherein the suction member is displaceable by means of a third movement axis which extends perpendicularly to the aforementioned plane;
displacing the bonding head by means of the first movement axis and the second movement axis in order to position the component in a target position above the substrate;
lowering the suction member by means of the third movement axis until the component touches the substrate, and producing a predetermined bonding force with which the suction member presses the component against the substrate; and
using a sensor to measure at least one of:
a potentially inclined position of the suction member,
a physical quantity dependent on an inclined position of the suction member, and
at least one shearing force which exists as a result of a force acting by the bonding head on the suction member.

9. The apparatus of claim 8, further configured to perform:
stopping the mounting when at least one of:
a measured torque exceeds a limit value, and
a measured shearing force exceeds a limit value.

10. The apparatus of claim 8, wherein the sensor is a multi-axis force-torque sensor.
